(19) United States
(12) Patent Application Publication
(10) Pub. No.: US 2024/0145637 A1
(43) Pub. Date: May 2, 2024

(54) DISPLAY PANEL, DISPLAY DEVICE AND MANUFACTURING METHOD THEREOF

(71) Applicant: Shenzhen China Star Optoelectronics Semiconductor Display Technology Co., Ltd., Shenzhen (CN)

(72) Inventors: Hong YANG, Shenzhen (CN); Jia TANG, Shenzhen (CN)

(73) Assignee: Shenzhen China Star Optoelectronics Semiconductor Display Technology Co., Ltd., Shenzhen (CN)

(21) Appl. No.: 18/194,081

(22) Filed: Mar. 31, 2023

(30) Foreign Application Priority Data
Nov. 2, 2022 (CN) 202211367293.8

(51) Int. Cl. H01L 33/46; H01L 33/38; H01L 33/40

(52) U.S. Cl. CPC H01L 33/46; H01L 33/38; H01L 33/405; H01L 2933/0016; H01L 2933/0025

(57) ABSTRACT

An embodiment of the present disclosure is directed to a display panel, a display device, and a manufacturing method thereof. The display panel includes an array substrate, an anode layer positioned on the array substrate, and a light-emitting layer. The anode layer includes a reflective layer and a first electrode layer positioned sequentially along a direction away from the array substrate. The reflector layer has reflective surfaces on one side of the reflector layer facing away from the array substrate. Two adjacent reflective surfaces are intersected. When the light emitted by the light-emitting layer passes through the first electrode layer and reaches the reflective layer, it can be reflected at different reflection angles after being reflected, thereby increasing the luminous angle of the light-emitting layer and improving the luminous viewing angle of the display panel.

### CROSS REFERENCE TO RELATED APPLICATION

This application claims the priority of Chinese Patent Application No. 202211367293.8, entitled “DISPLAY PANEL, DISPLAY DEVICE AND MANUFACTURING METHOD THEREOF”, filed on Nov. 2, 2022, the disclosure of which is incorporated herein by reference in its entirety.

### FIELD OF THE DISCLOSURE

The present disclosure relates to a display technology, and more particularly, to a display panel, a display device, and a manufacturing method thereof.

### BACKGROUND

With the rapid development of the display technology, the demand for large-size display panels (especially the top-emitting display panels) is also increasing. Conventionally, the top-emitting display panel uses reflective anode and semi-reflective semi-transparent cathode to form a microcavity. Through the mutual cooperation between the microcavity structure and the light-emitting material to enhance the microcavity benefit, the luminous efficiency of the light emitting pixels is greatly improved. However, the light emitted by the light emitting layer in the conventional display panel is more concentrated, so that the luminous viewing angle of the display panel is small, which affects the display quality of the display panel.

### SUMMARY

One objective of an embodiment of the present disclosure is to provide a display panel, a display device, and a manufacturing method thereof to alleviate the above-mentioned small luminous viewing angle issue.

According to an embodiment of the present disclosure, a display panel is disclosed. The display panel includes an array substrate, an anode layer positioned on the array substrate, and a light-emitting layer. The anode layer includes a reflective layer and a first electrode layer positioned sequentially along a direction away from the array substrate. The reflector layer has a plurality of reflective surfaces on one side of the reflector layer facing away from the array substrate. Two adjacent reflective surfaces are intersected. The light-emitting layer is positioned on one side of the first electrode layer facing away from the array substrate.

Optionally, the anode layer further comprises a second electrode layer positioned between the reflective layer and the array substrate.

Optionally, the second electrode layer comprises a first opening on one side of the second electrode layer facing away from the array substrate. The reflective layer is partially located within the first opening so that the reflective layer has a concave area corresponding to the first opening on one side of the reflective layer facing away from the array substrate.

Optionally, the first opening extends along a thickness direction of the second electrode layer and runs through the second electrode layer.

Optionally, a side wall of the first opening and a side of the second electrode facing the array substrate form an angle between 5 degrees to 80 degrees.

Optionally, the reflective layer comprises a second opening on one side of the reflective layer facing away from the array substrate. A depth of the second opening is less than a thickness of the reflective layer.

Optionally, a sidewall of the second opening and a side of the second electrode facing the array substrate form an angle between 5 degrees to 80 degrees.

According to an embodiment of the present disclosure, a display device is disclosed. The display device comprises the above-mentioned display panel.

According to an embodiment of the present disclosure, a method for manufacturing a display panel is disclosed. The method comprises: providing an array substrate; depositing a reflective layer on the array substrate so that the reflector layer forms a plurality of reflective surfaces on one side of the reflector layer facing away from the array substrate, wherein two adjacent reflective surfaces intersected; depositing a first electrode layer on the side of the reflector layer facing away from the array substrate; and forming a light-emitting layer on the side of the reflector layer facing away from the array substrate.

Optionally, the step of depositing the reflective layer on the array substrate comprises: depositing a second electrode layer on the array substrate; etching the second electrode layer to form a first opening on one side of the second electrode layer facing away from the array substrate; and depositing a reflective layer on the side of the second electrode layer facing away from the array substrate, so that the reflective layer is partially positioned within the first opening and the reflective layer has a concave area corresponding to the first opening on one side of the reflective layer facing away from the array substrate.

Optionally, the step of depositing the reflective layer on the array substrate so that the reflector layer forms the plurality of reflective surfaces on one side of the reflector layer facing away from the array substrate comprises: depositing a reflective layer on the array substrate; and etching reflective layer to form a second opening on a side of the reflective layer facing away from the array substrate. A depth of the second opening is less than a thickness of the reflective layer so that forms the plurality of reflective surfaces on the side of the reflector layer facing away from the array substrate.

The present disclosure forms a plurality of reflective surfaces on one side of the reflective layer facing away from the array substrate, and the adjacent two reflective surfaces are intersected. In this way, when the light emitted by the light-emitting layer passes through the first electrode layer and reaches the reflective layer, it can be reflected at different reflection angles after being reflected by the plurality of reflective surfaces of the reflective layer, thereby increasing the luminous angle of the light-emitting layer and improving the luminous viewing angle of the display panel.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 illustrates a display panel according to an embodiment of the present disclosure.

FIG. 2 illustrates a display panel according to another embodiment of the present disclosure.

FIG. 3 illustrates a display panel according to another embodiment of the present disclosure.

FIG. 4 illustrates a display panel according to another embodiment of the present disclosure.

FIG. 5 is a diagram of a display device according to an embodiment of the present disclosure.

FIG. 6 is a flow chart of a manufacturing method of a display panel according to an embodiment of the present disclosure.

FIG. 7 is a diagram of a structure at the block S200 shown in FIG. 6 according to an embodiment of the present disclosure.

FIG. 8 is a diagram of a structure at the block S200 shown in FIG. 6 according to another embodiment of the present disclosure.

FIG. 9 is a diagram of a structure at the block S300 shown in FIG. 6 according to an embodiment of the present disclosure.

FIG. 10 is a diagram of a structure at the block S300 shown in FIG. 6 according to another embodiment of the present disclosure.

### DETAILED DESCRIPTION OF PREFERRED EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

In the disclosure, it is should be understood that spatially relative terms, such as “center”, “longitudinal”, “lateral”, “length”, “width”, “above”, “below”, “front”, “back”, “left”, “right”, “horizontal”, “vertical”, “top”, “bottom”, “inner”, “outer”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. The spatially relative terms are not limited to specific orientations depicted in the figures. In addition, the term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features. In the description of the present disclosure, the meaning of “plural” is two or more, unless otherwise specifically defined.

Embodiments of the present disclosure are directed to a display panel, a display device, and a manufacturing method thereof. It should be noted that the description sequence of the following embodiments is not intended to limit the preferred sequence of the embodiments.

Please refer to FIGS. 1-4. A display panel is disclosed according to an embodiment of the present disclosure. The display panel 100 includes an array substrate 110. The array substrate 110 comprises a thin-film transistor (TFT) layer, which is used as a switching functional layer of the display panel 100, for controlling the display modes of the display panel 100.

Thin-film transistors in the TFT layer can be Low Temperature Poly-Silicon (LTPS) thin-film transistors, oxide thin-film transistors or Solid Phase Crystallization (SPC) thin-film transistors. Their structure type can be any type such as top gate structure, bottom gate structure or double gate structure. These modifications all fall within the scope of the present disclosure.

The display panel 100 includes an anode layer 130. The anode layer 130 is position on the array substrate 110. The anode layer 130 includes a reflective layer 132 and a first electrode layer 131 positioned sequentially along the direction away from the array substrate 110. The first electrode layer 131 is a transparent electrode, so that the light emitted from the inside of the display panel 100 can pass through the first electrode layer 131 to the reflective layer 132, and then be reflected by the reflective layer 132, thereby increasing the light output rate of the display panel 100. In addition, the reflective layer 132 can also reflect the external ambient light to avoid the ambient light reaching the display panel 100 and affecting the display effect of the display panel 100.

The reflective layer 132 comprises a plurality of reflective surfaces 1321 on one side of the reflective layer 132 facing away from the array substrate 110, and the adjacent two reflective surfaces 1321 are intersected. That is, the side of the reflective layer 132 facing away from the array substrate 110 is not a flat plane, but is formed by connecting multiple planes at an angle to form a plurality of reflective surfaces 1321. This structural design makes the light emitted from the inside the display panel 100 be reflected by a plurality of reflective surfaces 1321 of the reflective layer 132 at different reflection angles. This increases the overall light emitting viewing angle of the display panel 100 and improves the display effect of the display panel 100.

The display panel 100 includes a light-emitting layer 150. The light-emitting layer 150 is positioned on a side of the first electrode layer 131 facing away from the array substrate 110. By inputting a control signal onto the first electrode layer 131, the light-emitting layer 150 can be controlled to emit light. Before forming the light-emitting layer 150, it is necessary to form a pixel definition layer 140 and open a pixel opening on the pixel definition layer 140, so that the pixel opening exposes a part of the anode layer 130, and then the light-emitting layer 150 is provided in the pixel opening to achieve the definition of the position of the light-emitting pixel. Some of the light emitted by the light-emitting layer 150 will pass through the first electrode layer 131 to the reflective layer 132 and be reflected by a plurality of reflective surfaces 1321 of the reflective layer 132 at different angles, thereby increasing the light emitting angle of the light-emitting layer 150.

The light-emitting layer 150 may be formed on the first electrode layer 131 by evaporation or inkjet printing. Since one side of the reflective layer 132 facing away from the array substrate 110 comprises a plurality of intersecting reflective surfaces 1321, after the first electrode layer 131 is deposited on the reflective layer 132, the side of the reflective layer 132 facing away from the array substrate 110 is not a flat plane. At this time, using the deposition to form the light-emitting layer 150 could help ensure the uniformity of the thickness of the light-emitting layer 150, thereby improving the display effect of the display panel 100.

The display panel 100 includes an array substrate 110, an anode layer 130 and a light emitting layer 150. The anode layer 130 is positioned on the array substrate 110. The anode layer 130 includes a reflective layer 132 and a first electrode layer 131 arranged sequentially along the direction away from the array substrate 110. The reflective layer 132 comprises has a plurality of reflective surfaces 1321 on one side of the reflective layer 132 facing away from the array substrate 110. Two adjacent reflective surfaces 1321 are intersected. The light-emitting layer 150 is positioned on one side of the first electrode layer 131 facing away from the array substrate 110. By forming a plurality of reflective surfaces 1321 on one side of the reflective layer 132 facing away from the array substrate 110 where the adjacent two reflective surfaces 1321 are intersected, the light emitted by the light-emitting layer 150 passes through the first electrode layer 131 to the reflective layer 132 and is being reflected by the plurality of reflective surfaces 1321 of the reflective layer 132 at different reflection angles. This increases the light emitting angle of the light-emitting layer 150 and improves the overall light emitting viewing angle of the display panel 100.

Optionally, the anode layer 130 further comprises a second electrode layer 133. The second electrode layer 133 is positioned between the reflective layer 132 and the array substrate 110. That is, the anode layer 130 comprises stacked a second electrode layer 133, a reflective layer 132 and a first electrode layer 131. Before forming an anode layer 130 on the array substrate 110, a planarization layer 120 needs to be formed on the array substrate 110 to planarize the surface of the array substrate 110 for subsequent film fabrication.

The planarization layer 120 is an organic layer, which contains water and other substances. If the reflective layer 132 is directly disposed on the planarization layer, the water and other substances in the planarization layer 120 may erode the reflective layer 132 and thus affect the structural stability of the anode layer 130. Thus, by providing a second electrode layer 133 between the reflective layer 132 and the planarization layer 120, it helps ensure the structural stability of the reflective layer 132, thereby contributing to the overall display effect of the display panel 100.

Optionally, a second electrode layer 133 has a first opening 1331 on one side of the second electrode layer 133 facing away from the array substrate 110 such that the reflective layer 132 is partially located within the first opening 1331, so that the reflective layer 132 has a concave region corresponding to the position of the first opening 1331 on the side of the reflective layer 132 facing away from the array substrate 110, thereby forming a plurality of reflective surfaces 1321.

When forming the second electrode layer 133, the first opening 1331 is formed on one side of the second electrode layer 133 facing away from the array substrate 110 of the second electrode layer 133 so that one side of the second electrode layer 133 facing away from the array substrate 110 comprises a plurality of intersected surfaces. And then, a reflective layer 132 and a first electrode layer 131 are uniformly deposited on the second electrode layer 133 in turn, so that the side of the reflective layer 132 facing away from the array substrate 110 forms a plurality of intersected reflective surfaces 1321. The surface structures of the reflective surfaces 1321 and the side of the second electrode layer 133 facing away from the array substrate 110 can be consistent.

Because the material of the reflective layer 132 is a metal, its own internal resistance is small compared to the first electrode layer 131 and the second electrode layer 133. This structural design may ensure the uniformity of the thickness of the reflective layer 132, thereby reducing the overall internal resistance of the anode layer 130 and improving the display effect of the display panel 100.

As shown in FIG. 1, the first opening 1331 extends along the thickness direction of the second electrode layer 133 and runs through the second electrode layer 133. That is, the second electrode layer 133 is not a continuous film layer after the patterning process. This structural design allows the reflective layer 132 to have a larger reflection area 1321 formed at an angle to the initial horizontal plane given the same thickness of the reflective layer 132. This could reflect more light emitted by the light-emitting layer 150 from the reflective surfaces 1321. This could further increase the overall light emitting angle of the light-emitting layer 150 to improve the light emitting viewing angle of the display panel 100.

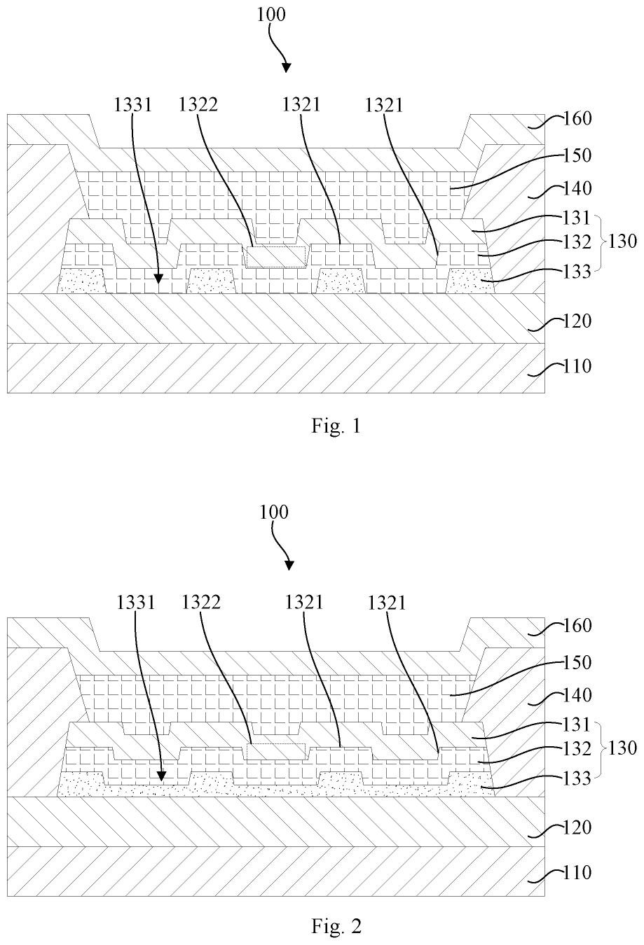

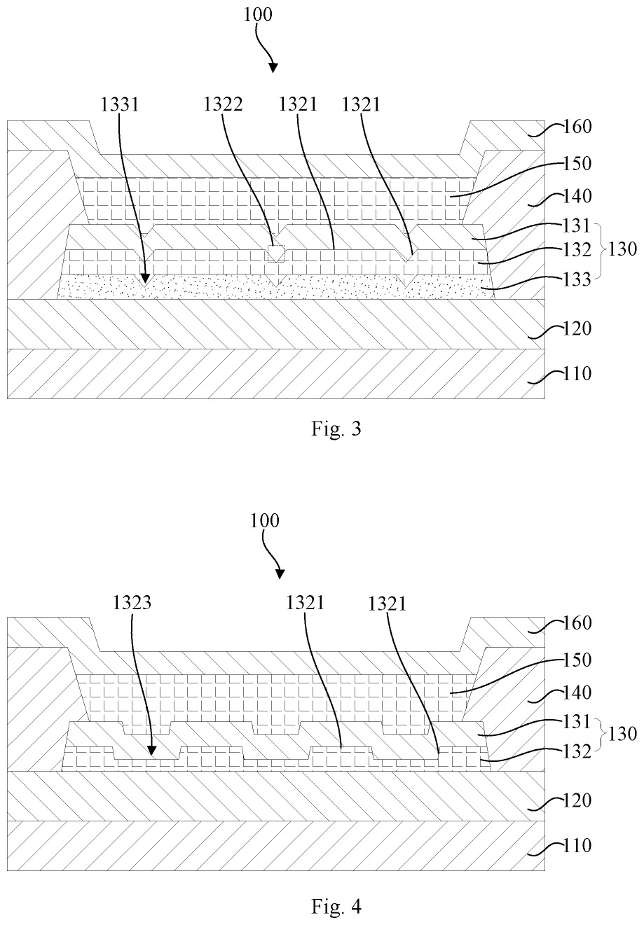

In another embodiment, as shown in FIG. 2 and FIG. 3, the depth of the first opening 1331 is less than the thickness of the second electrode layer 133. That is, the second electrode layer 133 is still a continuous film after the patterning process. This structural design makes it possible to reduce the segment difference between the reflective layer 132 and the first electrode layer 131 given the same thickness, thereby improving the thickness uniformity of the subsequent light-emitting layer 150 and improving the display effect of the display panel 100. In addition, this structural design can also reduce the erosion of water vapor on the reflective layer 132, ensure the structural stability of the reflective layer 132, and ensure the overall display effect of the display panel 100.

The specific depth value of the first opening 1331 can be adjusted accordingly according to the actual design and use. There is no limitation here as long as the first opening 1331 can make the side of the reflective layer 132 facing away from the array substrate 110 form a plurality of reflective surfaces 1321 to increase the light emitting angle of the light-emitting layer 150 and to improve the light emitting viewing angle of the display panel 100.

The sidewall of the first opening 1331 and the side of the second electrode layer 133 facing away from the array substrate 110 form an angle greater than or equal to 5 degrees and less than or equal to 80 degree. Because the reflective surface 1321 of the reflective layer 132 and the side of the second electrode layer 133 facing away from the array substrate 110 could have a consistent surface structure, the reflective surface 1321 of the reflection layer 132 corresponding to the sidewall of the first opening 1331 and the reflective surface 1321 in the horizontal position on the reflective layer 132 could form an angle between 5 degrees to 80 degrees.

If the angle is too small, then the angle between the reflective surface 1321 of the reflection layer 132 corresponding to the sidewall of the first opening 1331 and the reflective surface 1321 in the horizontal position on the reflective layer 132 is too small, after the light emitting layer 150 emits light to the reflection layer 132, the angle difference of the reflected light reflected by the reflection surfaces 1321 is small, so that it cannot effectively increase the light emitting angle of the light emitting layer 150. If the angle is too large, the reflective surface 1321 corresponding to the sidewall of the first opening 1331 and the reflective surface 1321 in the horizontal position on the reflective layer 132 tends to be perpendicular. In this way, the light emitted by the light emitting layer 150 cannot effectively reaches the reflective surface 1321 corresponding to the sidewall of the first opening 1331. This cannot effectively increase the light-emitting angle of the light-emitting layer 150 as well.

The angle between the sidewall of the first opening 1331 and the side of the second electrode layer 133 facing the array substrate 110 is set to 5 degrees, 10 degrees, 20 degrees, 50 degrees or 80 degrees, etc. Its specific value can be adjusted according to the actual design and use as long as it could ensure that the first opening 1331 can effectively increase the light-emitting angle of the light-emitting layer 150 and thus improve the overall light emitting viewing angle of the display panel 100. There is no limitation here.

The angle formed between the sidewall of the first opening 1331 and the side of the second electrode layer 133 facing the array substrate 110 refers to the angle formed between surface of the sidewall of the first opening 1331 and the surface of the side of the second electrode layer 133 facing the array substrate 110. The angle formed by the two surfaces includes an obtuse angle and an acute angle. Here, the acute angle is used to represent the angle.

As shown in FIG. 4, the reflective layer 132 has a second opening 1323 on a side of the reflective layer 132 facing away from the array substrate 110. The depth of the second opening 1323 is less than the thickness of the reflective layer 132. The inner wall of the second opening 1323 forms a partial reflective surface 1321 in the reflective layer 132. That is, when the reflective layer 132 is formed, the reflective layer 132 can be directly patterned to form a second opening 1323 on the reflective layer 132, thereby forming a plurality of reflective surfaces 1321. This could ensure the continuity of the reflective layer 132 so that the reflective layer 132 is set on the whole surface. This structural design enables a plurality of reflective surfaces 1321 of the reflective layer 132 to be obtained by the structural adjustment of the reflective layer 132 itself, which makes the arrangement of a plurality of reflective surfaces 1321 more flexible and convenient.

The sidewall of the second opening 1323 and the side of the reflective layer 132 facing the array substrate 110 form an angle greater than or equal to 5 degrees and less than or equal to 80 degrees. If the angle is too small, then the angle difference between the reflective surface 1321 corresponding to the sidewall of the second opening 1323 and the reflective surface 1321 located in the horizontal position on the reflective layer 132 is too small. Accordingly, the angle difference after reflection of the light-emitting layer 150 on the corresponding reflective surface 1321 is small so that it cannot effectively increase the light emitting angle of the light-emitting layer 150. If the angle is too large, it will cause the reflective surface 1321 corresponding to the sidewall of the second opening 1323 corresponding to the reflective surface 1321 and the reflective surface 1321 located in the horizontal position on the reflective layer 132 tend to be perpendicular. In this way, the light emitted by the light emitting layer 150 cannot effectively reaches the reflective surface 1321 corresponding to the sidewall of the second opening 1323 and also cannot effectively increase the light-emitting angle of the light-emitting layer 150.

The angle between the sidewall of the second opening 1323 and the reflective layer 132 facing the surface of the array substrate 110 is between 5 degrees and 80 degrees. The specific angle value can be adjusted according to the actual design and use as long as it could ensure that the second opening 1323 can effectively increase the light emitting angle of the light-emitting layer 150 and improve the overall light emitting viewing angle of the display panel 100. There is no limitation here.

In one embodiment, the second electrode layer 133 has a first opening 1331, the reflective layer 132 has a second opening 1323, and the first opening 1331 and the second opening 1323 are staggered in the thickness direction of the array substrate 110. This structural design can avoid the second electrode layer 133 or the opening on the reflective layer 132 is too dense, resulting in greater manufacturing process difficulty. Furthermore, this design can also increase the number of reflective surfaces 1321 and thus further increase the light emitting angle of the light-emitting layer 150, thereby improving the overall light emitting viewing angle of the display panel 100.

In this embodiment, the shape of the cross-sectional section of the first opening 1331 and the second opening 1323 in the thickness direction of the array substrate 110 can be one or more of the quadrilateral, triangular, semicircular or other polygons. The specific shape can be adjusted according to the actual use and manufacturing process. There is no limitation here.

When the shape of the cross-section of the first opening 1331 and the second opening 1323 in the thickness direction of the array substrate 110 is circular arc. That is, the sidewall of the first opening 1331 and the second opening 1323 is curved. The angle between the sidewall of the first opening 1331 and the second opening 1323 and the corresponding horizontal plane refers to the angle between the horizontal plane and the corresponding cut plane at any point on the sidewall of the first opening 1331 and the second opening 1323.

The materials of the first electrode layer 131 and the second electrode layer 133 are the same. The material of the first electrode layer 131 and the second electrode layer 133 includes a transparent material, such as indium tin oxide, so that the light emitted by the light-emitting layer 150 can pass through the first electrode layer 131 to the reflective layer 132 and then be reflected by the reflective layer 132, thereby improving the light output rate and light emitting viewing angle of the display panel 100. The material of the reflective layer 132 includes a metal material with a high reflectivity and a low resistance, such as silver or aluminum, which can ensure the effective reflection of the light emitted by the light-emitting layer 150 and reduce the overall internal resistance of the anode layer 130, thereby improving the display effect of the display panel 100.

According to an embodiment of the present disclosure, a display device is disclosed. The display device comprises a display panel. The specific structure of the display panel refers to the above embodiments. Because the display device adopts all the technical solutions of all the above embodiments, the display device at least has all the beneficial effects of the above embodiments. More details are omitted here for simplicity.

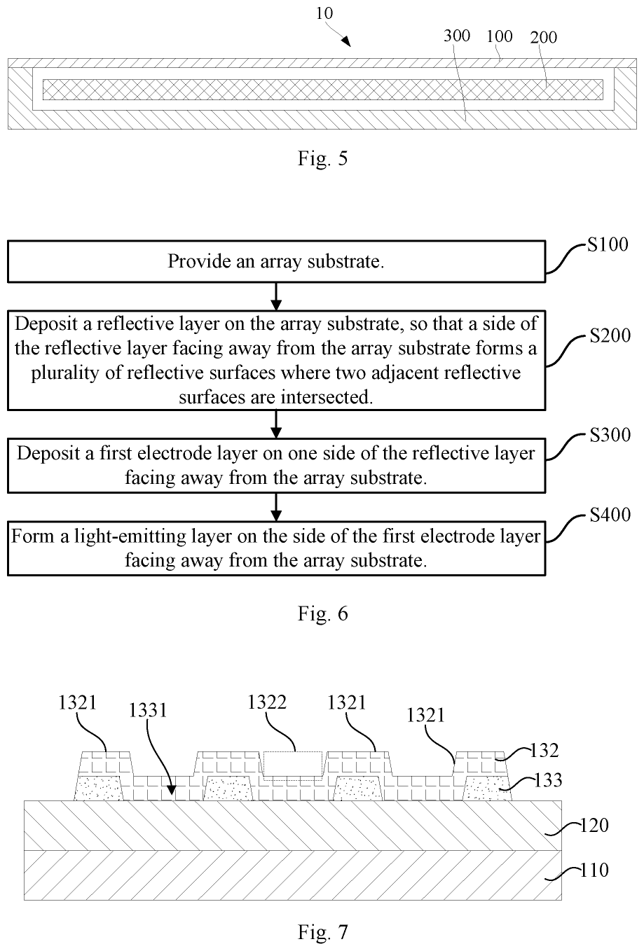

As shown in FIG. 5, the display device 10 includes a display panel 100, a control circuit 200 and a housing 300. The housing 300 is connected to the display panel 100 to support and fix the display panel 100. The control circuit 200 is positioned in the housing 300, and the control circuit 200 is electrically connected to the display panel 100 to control the display panel 100 for screen display.

The display panel 100 may be fixed to the housing 300 and forms a whole with the housing 300. The display panel 100 and the housing 300 form a confined space to accommodate the control circuit 200. The control circuit 200 may be the motherboard of the display device 10. In addition, the control circuit 200 may also integrate one or more of a battery, an antenna structure, a microphone, a speaker, a headphone interface, a universal serial bus interface, a camera, a distance sensor, an ambient light sensor, a processor and other functional components, so that the display device 10 can be adapted to various application fields.

The display device 10 may include a camera, an antenna structure, a fingerprint unlock module. These changes all fall within the scope of the present disclosure.

The display device 10 includes flexible displays and lighting, such as a television, a computer, a mobile phone, a foldable and rollable display, and/or include a wearable device, such as a smart bracelet, a smart watch, etc. These changes all fall within the scope of the present disclosure.

As shown in FIG. 6, according to an embodiment of the present disclosure, a method of manufacturing a display panel of any of the above-mentioned embodiments is disclosed. The method comprises following blocks S100, S200, S300 and S400.

At block S100, an array substrate 110 is provided.

When making the display panel 100, it is necessary to first form an array substrate 110. The array substrate 110 comprises a thin-film transistor (TFT) layer. The TFT layer is used as a switch function layer of the display panel 100 for the controlling the display modes of the display panel 100. The TFT layer can comprise LTPS (Low Temperature Poly-Silicon) thin-film transistors, oxide thin-film transistors or SPC (Solid Phase Crystallization) thin-film transistor. The structure type can be any type, such as a top-gate structure, a bottom-gate structure or a double-gate structure, and there are no limitations here.

At block S200, a reflective layer 132 is deposited on the array substrate 110, so that a side of the reflective layer 132 facing away from the array substrate 110 forms a plurality of reflective surfaces 1321 where two adjacent reflective surfaces 1321 are intersected.

After the array substrate 110 is formed, a reflective layer 132 is deposited on the array substrate 110, so that a side of the reflective layer 132 facing away from the array substrate 110 forms a plurality of reflective surfaces 1321. Here, the adjacent two reflective surfaces 1321 are intersected. That is, the side of the reflective layer 132 facing away from the array substrate 110 is not a flat plane, but is formed by connecting a plurality of planes at an angle, thereby forming a plurality of reflective surfaces 1321.

This structural design allows the light emitted from the inside the display panel 100 to reach the reflective layer 132 and to be reflected by the reflective layer 1321 at different reflection angles, thereby increasing the overall light emitting viewing angle of the display panel 100 and improving the display effect of the display panel 100. In addition, the arrangement of the reflective layer 132 can also reflect the ambient light to avoid the ambient light directly reaching the display panel 100 and affecting the display effect of the display panel 100.

Optionally, in step S200, a reflective layer 132 could be deposited on the array substrate 110 so that the side of the reflective layer 132 facing away from the array substrate 110 forms a plurality of reflective surfaces 1321.

As shown in FIG. 7, a second electrode layer 133 is deposited on the array substrate 110, and then the second electrode layer 133 is etched to form a first opening 1331 on the side of the second electrode layer 133 facing away from the array substrate 110. Next, a reflective layer 132 is deposited on one side of the second electrode layer 133 facing away from array substrate 110, so that the reflective layer 132 is partially located in the first opening 1331 to form a concave region 1322 at the side the side of the reflective layer 132 facing away from the array substrate 110 corresponding to the first opening 1331, thereby forming a plurality of reflective surfaces 1321.

The second electrode layer 133 is located between the reflective layer 132 and the array substrate 110. Before forming an anode layer 130 on the array substrate 110, a planarization layer 120 needs to be formed on the array substrate 110 to planarize the surface of the array substrate 110 for subsequent film fabrication. Since the planarization layer 120 is an organic layer, its interior contains water and other substances. If the reflective layer 132 is directly disposed on the planarization layer 120, the water and other substances in the planarization layer 120 may erode the reflective layer 132, thereby affecting the structural stability of the anode layer 130. Therefore, by providing a second electrode layer 133 between the reflective layer 132 and the planarization layer 120, it helps ensure the structural stability of the reflective layer 132, so as to ensure the overall display effect of the display panel 100.

When a second electrode layer 133 is formed, by forming a first opening 1331 on one side of the second electrode layer 133 facing away from the array substrate 110, the side of the second electrode layer 133 facing away from the array substrate 110 comprises a plurality of intersected surfaces. Then, a reflective layer 132 is uniformly deposited on the second electrode layer 133, so that the side of the second electrode layer 133 facing away from the array substrate 110 forms a plurality of intersected reflective surfaces 1321. The reflective surfaces 1321 and the side of the second electrode layer 133 facing away from the array substrate 110 could have a consistent surface structure.

Since the material of the reflective layer 132 is a metal, its own internal resistance is small compared to the second electrode layer 133. This structural design ensures the uniformity of the thickness of the reflective layer 132, thereby reducing the overall internal resistance of the anode layer 130 and further improving the display effect of the display panel 100.

The actual structure of the first opening 1331 can be referred to the above description of the display panel 100 in the above embodiment, and further illustrations are omitted herein.

In another embodiment, in step S200, a reflective layer 132 is deposited on the array substrate 110, so that a side of the reflective layer 132 facing away from the array substrate 110 forms a plurality of reflective surfaces 1321. The method mainly comprises the following:

As shown in FIG. 9, a reflective layer 132 is deposited on the array substrate 110, and then the reflective layer 132 is etched to form a second opening 1323 on one side of the reflective layer 132 facing away from the array substrate 110. Here, the depth of the second opening 1323 is less than the thickness of the reflective layer 132, so that the side of the reflective layer 132 facing away from the array substrate 110 form a plurality of reflective surfaces 1321.

That is, when the reflective layer 132 is formed, the reflective layer 132 can be directly patterned to form a second opening 1323 on the reflective layer 132, thereby forming a plurality of reflective surfaces 1321. This ensures the continuity of the reflective layer 132, so that the reflective layer 132 is set up as a whole. Furthermore, this structural design allows the multiple reflective surfaces 1321 of the reflective layer 132 to be obtained by the structural adjustment of the reflective layer 132 itself. This makes the arrangement of a plurality of reflective surfaces 1321 more flexible and convenient.

The specific structure of the second opening 1323 and the combination of the second opening 1323 and the first opening 1331 can refer to the relevant description of the display panel 100 in the above embodiments, and further illustrations are omitted herein.

At block S300, a first electrode layer 131 is deposited on one side of the reflective layer 132 facing away from the array substrate 110.

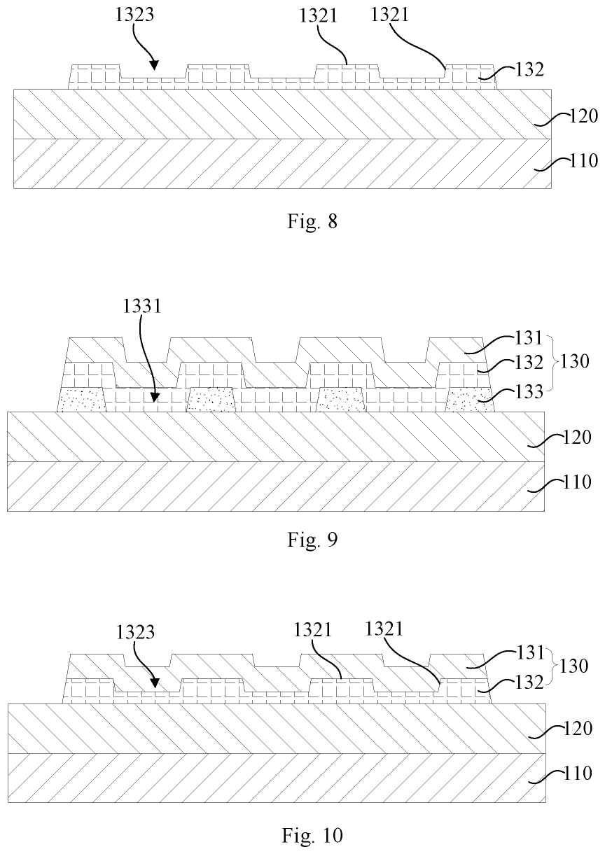

As shown in FIGS. 8 and 10, after the reflective layer 132 is formed, a first electrode layer 131 is uniformly deposited on the reflective layer 132, so that the surface shape of the first electrode layer 131 is consistent with the surface shape of the reflective layer 132. Here, the first electrode layer 131 and the reflective layer 132 constitute an anode layer 130. The first electrode layer 131 is a transparent electrode, so that the light emitted from the inside the display panel 100 can pass through the first electrode layer 131 to the reflection layer 132 and then be reflected by the reflection layer 132, thereby increasing the light output rate of the display panel 100.

At block S400, a light-emitting layer 150 is formed on the side of the first electrode layer 131 facing away from the array substrate 110.

After the anode layer 130 is completely manufactured, a light-emitting layer 150 is formed on the anode layer 130. By entering a control signal onto the first electrode layer 131, the light-emitting layer 150 can be controlled to emit light. Here, before forming the light-emitting layer 150, it is necessary to first coat a pixel definition layer 140, and then lithography process is performed on the pixel definition layer 140 to form a pixel opening on the pixel definition layer 140, so that the pixel opening exposes a part of the anode layer 130. Then, the light-emitting layer 150 is provided in the pixel opening to achieve the definition of the position of the luminous pixel.

The light-emitting layer 150 may be formed on the first electrode layer 131 by evaporation or inkjet printing. Since one side of the reflective layer 132 facing away from the array substrate 110 comprises a plurality of intersected reflective surfaces 1321, after the first electrode layer 131 is deposited on the reflective layer 132, the side of the reflective layer 132 facing away from the array substrate 110 is not a flat plane. At this time, the evaporation method to form the light-emitting layer 150 could ensure the uniformity of the thickness of the light-emitting layer 150, thereby improving the display effect of the display panel 100.

After the light-emitting layer 150 is completed, the method of manufacturing the display panel 100 further comprises forming a cathode layer 160 on the light-emitting layer 150. Through the input of the control signal onto the anode layer 130 and the cathode layer 160, the control of the display modes of the display panel 100 could be implemented, so as to meet the different display demands of the display panel 100.

Above are embodiments of the present disclosure, which does not limit the scope of the present disclosure. Any modifications, equivalent replacements or improvements within the spirit and principles of the embodiment described above should be covered by the protected scope of the disclosure.

What is claimed is:

1. A display panel, comprising:
an array substrate;
an anode layer, positioned on the array substrate, wherein the anode layer comprises a reflective layer and a first electrode layer positioned sequentially along a direction away from the array substrate; the reflector layer has a plurality of reflective surfaces on one side of the reflector layer facing away from the array substrate; and two adjacent reflective surfaces are intersected; and
a light-emitting layer, positioned on one side of the first electrode layer facing away from the array substrate.

2. The display panel of claim 1, wherein the anode layer further comprises:
a second electrode layer, positioned between the reflective layer and the array substrate.

3. The display panel of claim 2, wherein the second electrode layer comprises a first opening on one side of the second electrode layer facing away from the array substrate, and the reflective layer is partially located within the first opening so that the reflective layer has a concave area corresponding to the first opening on one side of the reflective layer facing away from the array substrate.

4. The display panel of claim 3, wherein the first opening extends along a thickness direction of the second electrode layer and runs through the second electrode layer.

5. The display panel of claim 1, wherein a side wall of the first opening and a side of the second electrode facing the array substrate form an angle between 5 degrees to 80 degrees.

6. The display panel of claim 1, wherein the reflective layer comprises:
a second opening on one side of the reflective layer facing away from the array substrate, wherein a depth of the second opening is less than a thickness of the reflective layer.

7. The display panel of claim 6, wherein a sidewall of the second opening and a side of the second electrode facing the array substrate form an angle between 5 degrees to 80 degrees.

8. A display device comprising a display panel, the display panel comprising:
an array substrate;
an anode layer, positioned on the array substrate, wherein the anode layer comprises a reflective layer and a first electrode layer positioned sequentially along a direction away from the array substrate; the reflector layer has a plurality of reflective surfaces on one side of the reflector layer facing away from the array substrate; and two adjacent reflective surfaces are intersected; and
a light-emitting layer, positioned on one side of the first electrode layer facing away from the array substrate.

9. The display device of claim 8, wherein the anode layer further comprises:
a second electrode layer, positioned between the reflective layer and the array substrate.

10. The display device of claim 9, wherein the second electrode layer comprises a first opening on one side of the second electrode layer facing away from the array substrate, and the reflective layer is partially located within the first opening so that the reflective layer has a concave area corresponding to the first opening on one side of the reflective layer facing away from the array substrate.

11. The display device of claim 10, wherein the first opening extends along a thickness direction of the second electrode layer and runs through the second electrode layer.

12. The display device of claim 8, wherein a side wall of the first opening and a side of the second electrode facing the array substrate form an angle between 5 degrees to 80 degrees.

13. The display device of claim 8, wherein the reflective layer comprises:
a second opening on one side of the reflective layer facing away from the array substrate, wherein a depth of the second opening is less than a thickness of the reflective layer.

14. The display device of claim 13, wherein a sidewall of the second opening and a side of the second electrode facing the array substrate form an angle between 5 degrees to 80 degrees.

15. A method for manufacturing a display panel, comprising:
providing an array substrate;
depositing a reflective layer on the array substrate so that the reflector layer forms a plurality of reflective surfaces on one side of the reflector layer facing away from the array substrate, wherein two adjacent reflective surfaces intersected;
depositing a first electrode layer on the side of the reflector layer facing away from the array substrate; and
forming a light-emitting layer on the side of the reflector layer facing away from the array substrate.

16. The method of claim 15, wherein the step of depositing the reflective layer on the array substrate comprises:
depositing a second electrode layer on the array substrate;
etching the second electrode layer to form a first opening on one side of the second electrode layer facing away from the array substrate;
depositing a reflective layer on the side of the second electrode layer facing away from the array substrate, so that the reflective layer is partially positioned within the first opening and the reflective layer has a concave area corresponding to the first opening on one side of the reflective layer facing away from the array substrate.

17. The method of claim 15, wherein the step of depositing the reflective layer on the array substrate so that the reflector layer forms the plurality of reflective surfaces on one side of the reflector layer facing away from the array substrate comprises:
depositing a reflective layer on the array substrate; and
etching reflective layer to form a second opening on a side of the reflective layer facing away from the array substrate, wherein a depth of the second opening is less than a thickness of the reflective layer so that forms the plurality of reflective surfaces on the side of the reflector layer facing away from the array substrate.
